(19) United States
(12) Patent Application Publication
(10) Pub. No.: US 2007/0246775 A1
(43) Pub. Date: Oct. 25, 2007

(54) SOI SUBSTRATE AND METHOD FOR FORMING THE SAME

(75) Inventors: Young-Soo PARK, Gyeonggi-do (KR); Kyoo-Chul CHO, Gyeonggi-do (KR); Soo-Yeol CHOI, Gyeonggi-do (KR); Tae-Soo KANG, Gyeonggi-do (KR); Yoon-Hee LEE, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/739,351

(22) Filed: Apr. 24, 2007

(30) Foreign Application Priority Data
Apr. 24, 2006 (KR) 2006-36698

(51) Int. Cl. H01L 27/12

(52) U.S. Cl. 257/347

(57) ABSTRACT

Provided are an SOI substrate, memory devices using the SOI substrate, and a method of manufacturing the same. The SOI substrate includes a thermal oxide layer pattern which minimizes leakage current but allows back biasing and heat dissipation through the substrate. The SOI substrate also includes a metal-gettering site to further minimize leakage current.

### CROSS-REFERENCE TO RELATED APPLICATIONS

This U.S. non-provisional patent application claims priority under 35 U.S.C. § 119 to Korean Patent Application No. 2006-36698, filed on Apr. 24, 2006, the contents of which are hereby incorporated by reference in their entirety.

### BACKGROUND

1. Technical Field

The invention disclosed herein relates to a semiconductor device and a method of manufacturing the same. Specifically, the present invention relates to a silicon on insulator (SOI) substrate, a method of manufacturing the SOI substrate, and memory devices utilizing the SOI substrate.

2. Description of the Related Art

Consumer demand for smaller, lighter, and/or higher performance electronic devices has put pressure on semiconductor device manufacturers to produce more highly integrated devices. As semiconductor devices are more highly integrated, the channel width of individual transistors on the semiconductor device becomes narrower. Various problems such as punch through or leakage current due to the narrow channels can occur. These problems are often called short channel effect. An SOI substrate has been suggested as one means to resolve these problems.

A conventional SOI substrate includes an insulation layer and a silicon single crystal layer, which are sequentially formed on a silicon substrate. A gate electrode and a conductive line are then formed on the silicon single crystal layer. Since the silicon single crystal layer is used as a device region, it should have an excellent quality without any crystal defects. When there are crystal defects in the silicon single crystal layer, a leakage current occurs in a PN junction region of a semiconductor device subsequently formed on the SOI substrate. Also, the quality of a gate insulation layer for the semiconductor device may deteriorate, and/or control of the threshold voltage in the device may become difficult. Since the insulation layer needs to prevent leakage current occurring in the PN junction region from flowing to the semiconductor substrate, the quality of the insulation layer is also important.

According to a conventional method for forming an SOI substrate, an oxide layer is formed on an entire surface of a first wafer, and a second wafer is attached to the oxide layer. Then, a portion of the second wafer is removed using a polishing process to form the SOI substrate. Since each SOI substrate requires two wafers, the manufacturing cost of the SOI substrate increases. Additionally, since the surface of the SOI substrate is polished, the surface becomes rougher than a conventional (non-SOI) substrate. Thus, the performance of a device subsequently manufactured on the SOT substrate deteriorates. Further, since an oxide layer is formed on an entire surface of the semiconductor substrate, the SOI substrate cannot have a path for applying back bias to, and dissipating heat from, devices subsequently manufactured on the SOI substrate. The inability to apply back bias to a device on an SOI substrate can limit the operational characteristics of the device. Also, the inability to dissipate heat from devices manufactured on an SOI substrate can lead to reliability concerns.

According to another conventional method for forming an SOI substrate, oxygen ions are implanted into one wafer using an ion implantation process and the resultant wafer is thermally treated to form an oxide layer at a predetermined depth in the wafer. In this case, since only one wafer is used, manufacturing costs are reduced. However, the silicon lattice of the wafer is damaged during the oxygen ion implantation. Consequently, the quality of the silicon single crystal layer on the surface of the SOI substrate is poor. Additionally, since the oxide layer is formed by an ion implantation process, it is difficult to completely prevent leakage current because of the irregular oxygen concentration of the oxide layer in the SOI substrate. Therefore, when a semiconductor device is formed using the SOI substrate, the reliability of the semiconductor device cannot be guaranteed.

The present invention addresses these and other disadvantages of the conventional art.

### SUMMARY

In one embodiment, this disclosure provides an SOI substrate having high quality insulation and semiconductor single crystal layers to provide high reliability semiconductor devices. This disclosure also provides a method of manufacturing the SOI substrate and memory devices using the SOI substrate.

### BRIEF DESCRIPTION OF THE DRAWINGS

The accompanying figures are included to provide a further understanding of the invention, and are incorporated in and constitute a part of this specification. The drawings illustrate exemplary embodiments of the invention and, together with the description, serve to explain principles of the invention. In the figures:

FIGS. 1 through 4 are sectional views illustrating a method for forming an SOI substrate according to a first embodiment of the invention;

FIG. 5 is a sectional view illustrating a process of forming the first semiconductor single crystal layer of FIG. 4 according to a first embodiment of the present invention;

FIG. 6 is a sectional view illustrating a process of forming the first semiconductor single crystal layer of FIG. 4 according to a second embodiment of the present invention;

FIGS. 7 and 8 are sectional views illustrating a method for forming an SOI substrate according to either of the embodiments of FIGS. 5 and 6;

FIG. 9 is a sectional view of a DRAM device according to a third embodiment of the invention;

FIG. 10 is a sectional view of a non-volatile memory device according to a fourth embodiment of the invention;

FIG. 11 is a perspective view of a FinFET device according to a fifth embodiment of the invention; and

FIG. 12 is a perspective view of a FinFET device according to a sixth embodiment of the invention.

### DETAILED DESCRIPTION OF PREFERRED EMBODIMENTS

Preferred embodiments of the invention will be described below in more detail with reference to the accompanying drawings. The invention may, however, be embodied in different forms and should not be constructed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

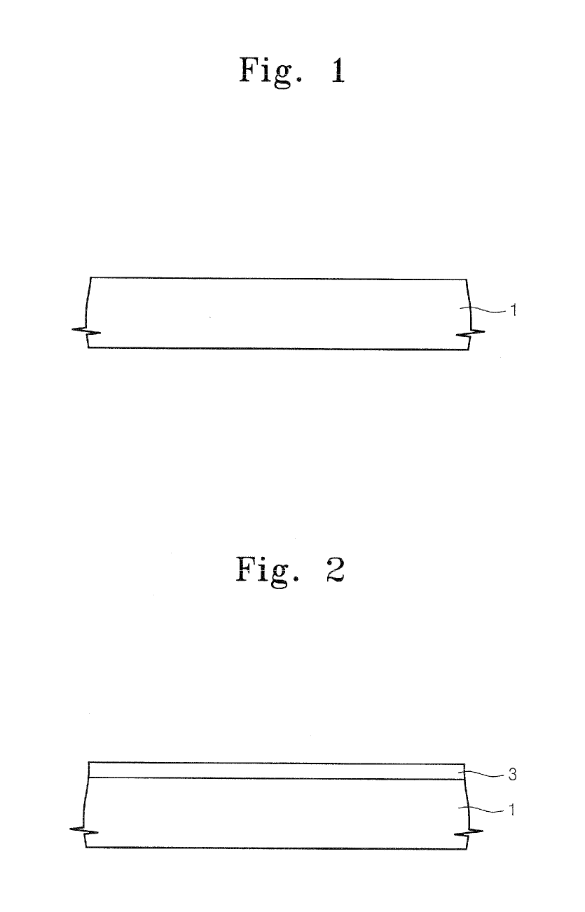

FIGS. 1 through 4 are sectional views illustrating a method for forming a silicon on insulator (SOI) substrate according to a first embodiment of the invention.

Referring to FIG. 1, a semiconductor substrate 1 is provided. The semiconductor substrate 1 is formed using a czochralski crystallization growth method. That is, after putting powder or poly-crystalline chunks of a semiconductor material, such as silicon or germanium, in a melting pot and melting the contents, a small crystalline seed is slowly immersed in the molten silicon or germanium, and then is lifted at a predetermined speed. The lifting speed can be 0.4 mm/min or 1.2 mm/min. When the lifting speed is 0.5 mm/min, the semiconductor substrate 1 can contain an oxygen concentration of approximately 7 to 17 parts per million atomic (ppma). When the lifting speed is about 0.7 to 1.2 mm/min, the semiconductor substrate 1 can contain an oxygen concentration of approximately 11 to 14 ppma. To form a metal-gettering site, it is better to use the semiconductor substrate 1 that is formed when the lifting speed is 1.2 mm/min. A chemical element such as boron can be added while the semiconductor substrate 1 is formed. In this case, the semiconductor substrate 1 can be a p-type silicon substrate.

Referring to FIG. 2, a thermal oxide layer 3 is formed on an entire surface of the semiconductor substrate 1. The thermal oxide layer 3 can be formed using a thermal oxidation process. Since the thermal oxide layer 3 has high quality and low impurity concentration, it is suitable for preventing leakage current. The thickness of the thermal oxide layer 3 may be about 5 to 1500 Å. The thermal oxide layer 3 may be substituted silicon nitride layer (SiN).

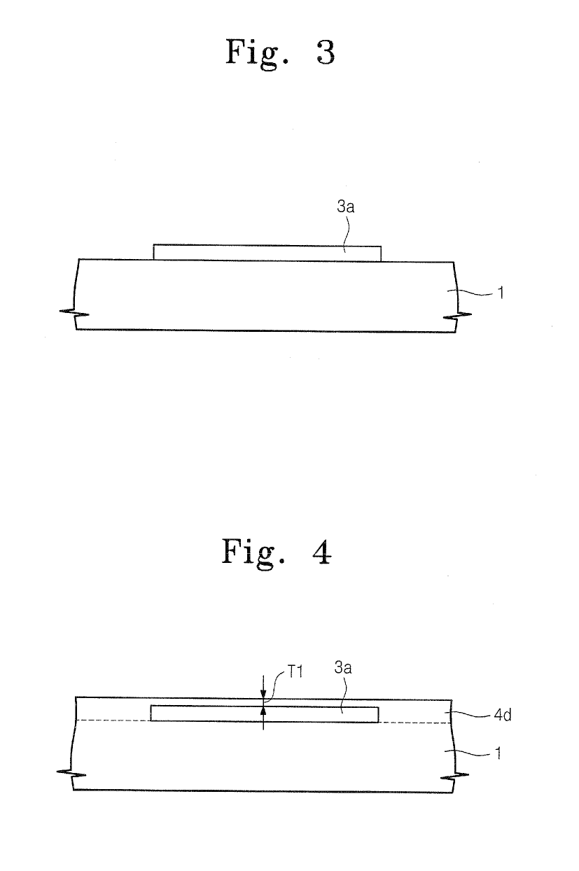

Referring to FIG. 3, the thermal oxide layer 3 is patterned to expose a portion of the semiconductor substrate 1 and to simultaneously form a thermal oxide layer pattern 3a. The patterning of the thermal oxide layer 3 can be performed using a photoresist pattern (not shown), which is formed using a photolithography process, as an etching mask.

Referring to FIG. 4, a first semiconductor single crystal layer 4d is formed to cover a sidewall and a top of the thermal oxide layer pattern 3a and the exposed surface of the semiconductor substrate 1. The first semiconductor single crystal layer 4d is formed to have a flat top surface. Additionally, the first semiconductor single crystal layer 4d has a first thickness T1 on the thermal oxide layer pattern 3a. The first thickness T1 is at least 10 Å. The first semiconductor single crystal layer 4d can include silicon atoms whose mass number is 28. Silicon includes three kinds of isotopes whose mass numbers are 28, 29 and 30, respectively. When the first semiconductor single crystal layer 4d includes silicon atoms whose mass number is 28, heat conductivity is improved compared to silicon atoms whose mass number is 29 or 30. Accordingly, the first semiconductor single crystal layer 4d adjacent to the sidewall of the thermal oxide layer pattern 3a can be easily used to dissipate heat generated during operation of a device subsequently fabricated on the SOI substrate.

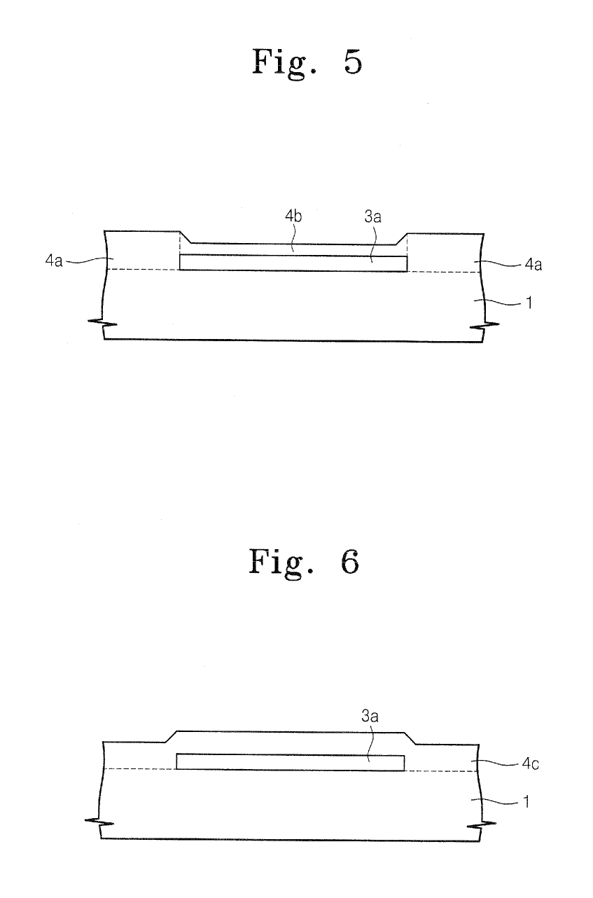

The first semiconductor single crystal layer 4d can be formed using a selective epitaxial growth (SEG) process or a solid phase epitaxial growth (SPE) process. This will be described with reference to FIGS. 5 and 6.

FIG. 5 is a sectional view illustrating a process of forming the first semiconductor single crystal layer of FIG. 4 according to a first embodiment of the present invention.

Referring to FIG. 5, epitaxial semiconductor layers 4a and 4b are grown from the exposed surface of the semiconductor substrate 1 having the thermal oxide layer pattern 3a using an SEG process. The epitaxial semiconductor layers 4a and 4b include a first epitaxial semiconductor layer 4a and a second epitaxial semiconductor layer 4b. The first epitaxial semiconductor layer 4a contacts the exposed top of the semiconductor substrate 1 and the sidewall of the thermal oxide layer pattern 3a. The second epitaxial semiconductor layer 4b contacts the top of the thermal oxide layer pattern 3a. The top of the first epitaxial semiconductor layer 4a may be formed higher than the top of the second epitaxial semiconductor layer 4b. The first epitaxial semiconductor layer 4a mainly has a single crystal structure and also may have crystal defects in a region adjacent to the sidewall of the thermal oxide layer pattern 3a. Most of the second epitaxial semiconductor layer 4b may have crystal defects. A first heat treatment process is performed to remove crystal defects and to provide a more complete single crystal structure in the epitaxial semiconductor layers 4a and 4b. The first heat treatment process may be performed over duration of between about 10 seconds and about 1 hour at a temperature between about 110° C. and about 1200° C. in an argon or hydrogen atmosphere. At this point, the argon atmosphere may be better than the hydrogen atmosphere for this process. Once the first heat treatment process is completed, the tops of the epitaxial semiconductor layers 4a and 4b are planarized, and then a planarization etching process such as chemical mechanical polishing (CMP) is performed to remove crystal defects that may be on the tops of the epitaxial semiconductor layers 4a and 4b. Thereby, the first semiconductor single crystal layer 4d of FIG. 4 is formed. The order of the first heat treatment process and the planarization etching process can be interchangeable.

FIG. 6 is a sectional view illustrating a process of forming the first semiconductor single crystal layer of FIG. 4 according to a second embodiment of the present invention.

Referring to FIG. 6, the first semiconductor single crystal layer 4d can be formed using an SPE process. That is, a semiconductor layer 4c is conformally deposited on an entire surface of the semiconductor substrate 1 having the thermal oxide layer pattern 3a. Conformal deposition of the semiconductor layer 4c leads to the semiconductor layer 4c having an approximately equal thickness across the entire semiconductor substrate 1. Accordingly, the top of the semiconductor layer 4c is high on the thermal oxide layer pattern 3a, and is low on the semiconductor substrate 1 adjacent to the sidewall of the thermal oxide layer pattern 3a. That is, the semiconductor layer 4c may include a top profile opposite to that of the epitaxial semiconductor layers 4a and 4b of FIG. 5. The semiconductor layer 4c may be amorphous silicon or polysilicon. Similar to the process described above with reference to FIG. 5, the first heat treatment process is performed to transform the semiconductor layer 4c into a single crystal structure. Then, the planarization etching process is performed to planarize the top of the semiconductor layer 4c and to remove crystal defects in a portion to be used as a device region in subsequent device fabrication. Thus, the first semiconductor single crystal layer 4d of FIG. 4 is formed.

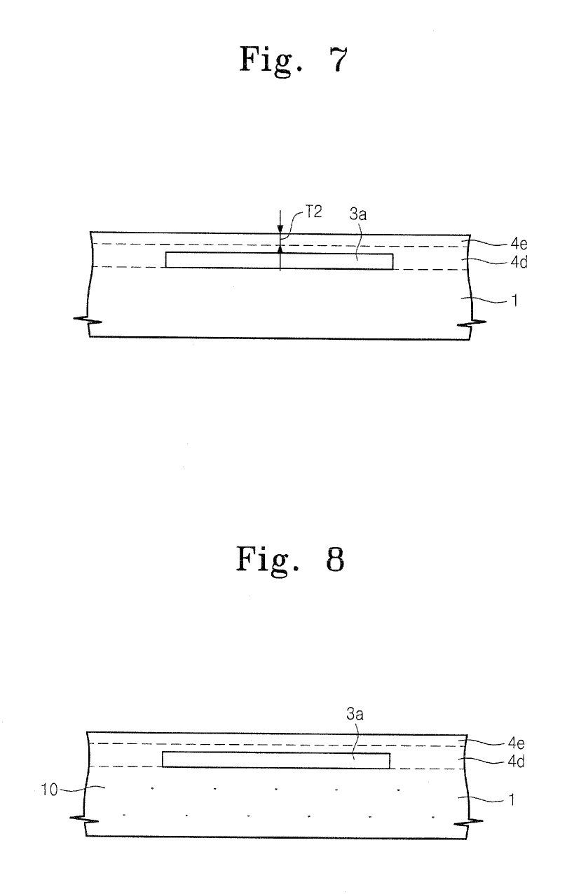

FIGS. 7 and 8 are sectional views illustrating a method for forming an SOI substrate according to either of the embodiments of FIGS. 5 and 6 above.

Referring to FIG. 7, a second semiconductor single crystal layer 4e is formed on the first semiconductor single crystal layer 4d. The second semiconductor single crystal layer 4e can be formed to have a thickness T2 of 0.5 to 5 μm using an SEG process. Since the first semiconductor single crystal layer 4d has a defect-free single crystal structure due to the first heat treatment process and the planarization process, the second semiconductor single crystal layer 4e grown from the first semiconductor single crystal layer 4d has a high quality and defect-free single crystal structure. Since the second semiconductor single crystal layer 4e, used as a device region in subsequent device fabrication processes, has excellent quality, leakage current can be minimized and the reliability of the semiconductor device is improved.

Referring to FIG. 8, a metal-gettering site 10 is formed in the semiconductor substrate 1. The metal-gettering site 10 is a site for gettering metal, and may be an oxygen precipitates whose size is 2 to 150 nm. The metal-gettering site 10 can be formed using two methods. In a first method, a second heat treatment process is performed on the semiconductor substrate 1 over duration of between 1 second and 1 minute at a temperature between about 1000° C. and about 1200° C. Then, nucleation sites are formed to shape the metal-gettering site 10 using quick freezing. Next, the size of the nucleation site becomes bigger, becoming the metal-gettering site 10, during the numerous subsequent heat treatment processes that are performed to fabricate transistors and conductive lines. In a second method, a third heat treatment process is performed over duration of between about 2 minutes and about 10 hours at a temperature between about 650° C. and about 800° C., and a fourth heat treatment process is performed over duration of between 2 minutes and 16 hours at a temperature between about 900° C. and about 1100° C. to form the metal gettering site 10, The metal-gettering site 10 can be formed substantially simultaneously with the process described above with reference to FIG. 1. Since the metal-gettering site 10 is formed using the above methods, the diffusion of metal atoms, can be prevented. The metal atoms can be introduced into the semiconductor substrate 1 due to semiconductor manufacturing processes such as a subsequent conductive line formation process. Without the metal-gettering site 10, these metal atoms can diffuse freely, facilitating leakage current. Since the semiconductor substrate 1 includes the metal-gettering site 10, the metal atoms do not contribute to the leakage current and thereby the leakage current can be minimized. Therefore, the SOI substrate according to the present invention can provide high reliability.

Referring to the SOI substrate of FIG. 8, the thermal oxide layer pattern 3a is disposed on the semiconductor substrate 1. If the thermal oxide layer 3 may be substituted silicon nitride layer described above with reference to FIG. 2, the thermal oxide layer pattern 3a may be substituted silicon nitride layer pattern. The first semiconductor single crystal layer 4d covers the top and the sidewall of the thermal oxide layer pattern 3a, and the top of the semiconductor substrate 1 adjacent to the sidewall of the thermal oxide layer pattern 3a. The second semiconductor single crystal layer 4e is disposed on the first semiconductor single crystal layer 4d. Since the first semiconductor single crystal layer 4d includes silicon atoms whose mass number is 28, thermal conductivity is improved and thus heat is easily dissipated during device operation. Since the thermal oxide layer pattern 3a is formed using a thermal oxide layer 3, the quality of the layer is improved. Thus, leakage current can be easily prevented. Additionally, since the second semiconductor single crystal layer 4e, used as a device region, has a defect-free single crystal structure, the reliability of the semiconductor device can be improved. Also, since the semiconductor substrate 1 includes the metal-gettering site 10, the diffusion of metal atoms can be prevented and leakage current can be reduced. Therefore, the SOI substrate can provide high reliability.

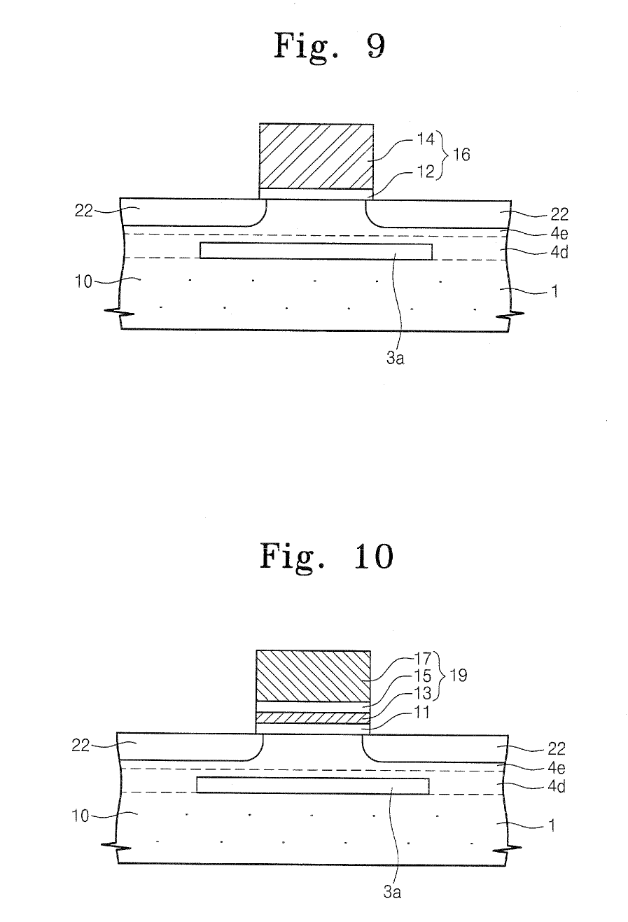

The SOI substrate can be applied to various semiconductor devices such as memory device. FIG. 9 is a sectional view of a dynamic random access memory (DRAM) device according to a third embodiment of the invention.

Referring to FIG. 9, the thermal oxide layer pattern 3a, the first semiconductor single crystal layer 4d, and the second semiconductor single crystal layer 4e are formed on the semiconductor substrate 1. A gate insulation layer and a gate electrode layer are sequentially formed, patterned and stacked on the semiconductor substrate 1 to form a gate insulation pattern 12 and a gate electrode pattern 14. Using the gate electrode pattern 14 as an ion implantation mask, an impurity implantation region 22 is formed on the top of the semiconductor substrate 1 to complete a DRAM device. The DRAM device of FIG. 9 may represent one cell transistor in a volatile memory device. A gate pattern 16 may comprise the gate insulation pattern 12 and the gate electrode pattern 14 which are sequentially stacked. Leakage current can be prevented using the thermal oxide layer pattern 3a.

FIG. 10 is a sectional view of a non-volatile memory device according to a fourth embodiment of the invention.

Referring to FIG. 10, the thermal oxide layer pattern 3a, the first semiconductor single crystal layer 4d, and the second semiconductor single crystal layer 4e are formed on the semiconductor substrate 1. A tunnel insulation layer, a charge storage layer, an interlayer dielectric layer and a gate electrode layer are sequentially formed, patterned and stacked on the semiconductor substrate 1 to form a tunnel insulation pattern 1, a charge storage pattern 13, an interlayer dielectric pattern 15 and a word line 17. Using the word line 17 as an ion implantation mask, an impurity implantation region 22 is formed on the top of the semiconductor substrate 1 to complete a non-volatile memory device.

The non-volatile memory device of FIG. 10 may represent one cell transistor in a flash memory device. A gate pattern 19 may comprise the tunnel insulation pattern 11, the charge storage pattern 13, the interlayer dielectric pattern 15 and the word line 17 which are sequentially stacked. Leakage current can be prevented using the thermal oxide layer pattern 3a. If the charge storage pattern 13 and the interlayer dielectric pattern 15 are a floating gate pattern and an interpoly dielectric pattern respectively, the non-volatile memory device of FIG. 10 may be a typical flash memory device. If the charge storage pattern 13 and the interlayer dielectric pattern 15 are a charge trap pattern and a blocking insulation pattern respectively, the non-volatile memory device of FIG. 10 may be a charge trap flash (CTF) memory device.

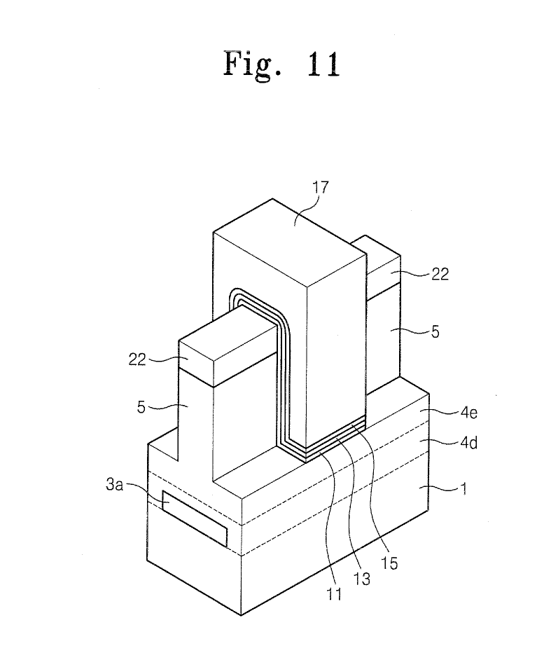

FIG. 11 is a perspective view of a fin field effect transistor (FinFET) device according to a fifth embodiment of the invention.

Referring to FIG. 1, the thermal oxide layer pattern 3a, the first semiconductor single crystal layer 4d, and the second semiconductor single crystal layer 4e are formed on the semiconductor substrate 1. A portion of the second semiconductor single crystal layer 4e is patterned to form a fin 5. A tunnel insulation layer, a charge trap layer, a blocking insulation layer, and a gate electrode layer are sequentially formed, patterned and stacked on the semiconductor substrate 1 having the fin 5 to form a tunnel insulation pattern 11, a charge trap pattern 13, a blocking insulation pattern 15, and a word line 17 crossing over the fin 5. Using the word line 17 as an ion implantation mask, an impurity implantation region 22 is formed on the top of the fin 5 to complete a FinFET device.

The FinFET device of FIG. 11 may represent one cell transistor in a charge trap-type non-volatile memory device. Referring to FIG. 11, since the word line 17, the tunnel insulation pattern 11, the charge trap pattern 13, and the blocking insulation pattern 15 cover the sidewall and the top of the fin 5, the channel length becomes longer, and thus punch through due to short channel effect can be prevented. Moreover, leakage current can be prevented using the thermal oxide layer pattern 3a.

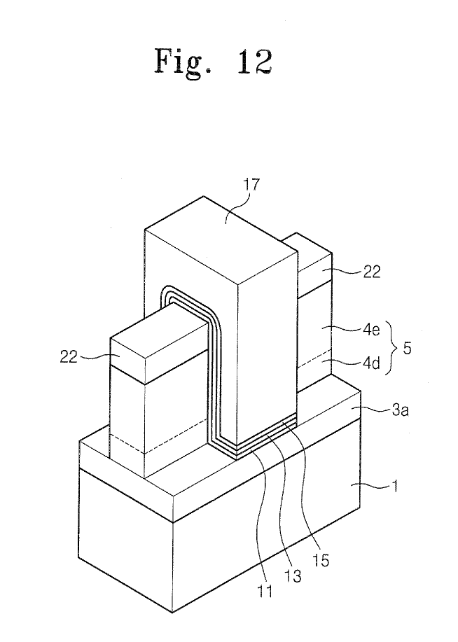

FIG. 12 is a perspective view of a FinFET device according to a fourth embodiment of the invention.

Referring to FIG. 10, the second semiconductor single crystal layer 4e and the first semiconductor single crystal layer 4d are sequentially patterned to form the fin 5 and to expose the thermal oxide layer pattern 3a. The fin 5 includes the second semiconductor single crystal layer 4e and the first semiconductor single crystal layer 4d. The tunnel insulation pattern 11 contacts the thermal oxide layer pattern 3a. Other components are identical to that of FIG. 9. Therefore, the fin 5 can be completely isolated from a fin of an adjacent device (not shown) to the fin 5. Leakage current, which flows into adjacent memory cell transistors and occurs during device operation, can be prevented using the thermal oxide layer pattern 3a. Additionally, since the second semiconductor single crystal layer 4e has high quality, a reliable FinFET device can be achieved.

In accordance with the SOI substrate and the method of manufacturing the same described above, since a thermal oxide layer is formed on a semiconductor substrate, an oxygen concentration in the oxide layer is uniform and the quality of the layer is high. Therefore, leakage current can be completely prevented. Since the thermal oxide layer is patterned and a first semiconductor single crystal layer contacting the semiconductor substrate is formed, a path for thermal dissipation (emission) or back bias can be formed. Since the first semiconductor single crystal layer is formed using an SEG/SPE process and a heat treatment process, crystal defects such as lattice damage of the first semiconductor single crystal layer can be minimized. Moreover, even though these defects exist in the first semiconductor single crystal layer, the defects can be removed because the top of the first semiconductor single crystal layer is removed using a planarization process. Additionally, since a second semiconductor single crystal layer is formed without the above defects, it is defect-free and has an excellent quality compared to the related art. Therefore, a reliable SOI substrate can be achieved.

Embodiments of the present invention provide a method for forming an SOI substrate, the method including: preparing a semiconductor substrate; forming a thermal oxide layer on the semiconductor substrate; patterning the thermal oxide layer to form a thermal oxide layer pattern and to expose a portion of the semiconductor substrate; forming a first semiconductor single crystal layer covering a sidewall and a top of the thermal oxide layer pattern and contacting the exposed semiconductor substrate; and forming a second semiconductor single crystal layer on the first semiconductor single crystal layer.

In some embodiments, the forming of the first semiconductor single crystal layer can be performed using an SEG (selective epitaxial growth) process or an SPE (solid phase epitaxial growth) process. The forming of the first semiconductor single crystal layer includes: growing an epitaxial semiconductor layer from the exposed semiconductor substrate using an SEG process; and performing a heat treatment process. The forming of the first semiconductor single crystal layer includes: forming a semiconductor layer using a deposition method; and performing a heat treatment process. The heat treatment process is performed for duration of between about 10 seconds and about 1 hour at a temperature between about 110 and about 1200° C. in an argon or hydrogen atmosphere. The semiconductor layer is formed of one of amorphous silicon and polysilicon.

In other embodiments, the first semiconductor single crystal layer includes silicon atoms whose mass number is 28. The semiconductor substrate includes oxygen atoms of an 8 to 14 ppma concentration and may include oxygen atoms of an 11 to 14 ppma concentration.

In still other embodiments, the method further includes forming a metal-gettering site on the semiconductor substrate. The forming of the metal-gettering site includes performing a heat treatment process for duration of between about 1 second and about 1 minute at a temperature between about 1000° C. and about 1200° C. The forming of the metal-gettering site includes: performing a first heat treatment process for duration of between about 2 minutes and about 10 hours at a temperature between about 650 and about 800° C.; and performing a second heat treatment process for duration of between about 2 minutes and about 16 hours at a temperature between about 900° C. and about 1100° C.

According to some embodiments, the removing of the portion of the top of the first semiconductor single crystal layer using the planarization process includes leaving the first semiconductor single crystal layer having a thickness of at least about 10 Å on the thermal oxide layer pattern. The thermal oxide layer has a thickness of about 5 Å to about 1500 Å. The second semiconductor single crystal layer may have a thickness of about 0.5 μm to about 5 μm.

In yet other embodiments, the second semiconductor single crystal layer is formed using an SEG process.

In other embodiments of the present invention, an SOI substrate is provided including: a semiconductor substrate; a thermal oxide layer pattern provided on the semiconductor substrate; a first semiconductor single crystal layer contacting a top and a sidewall of the thermal oxide layer pattern and a top of the semiconductor substrate adjacent to the sidewall of the thermal oxide layer pattern; and a second semiconductor single crystal layer provided on the first semiconductor single crystal layer.

In still other embodiments of the present invention, a memory device is provided including: the SOI substrate described above; a gate pattern disposed on the SOI substrate; and an impurity implantation region disposed in the SOI substrate and adjacent to the gate pattern.

In some embodiments, the gate pattern comprises a gate insulation pattern and a gate electrode pattern which are sequentially stacked. The gate pattern comprises a tunnel insulation pattern, a charge storage pattern, an interlayer dielectric pattern and a word line which are sequentially stacked. The charge storage pattern is one of a floating gate and a charge trap pattern. The interlayer dielectric pattern is one of an interpoly dielectric pattern and a blocking insulation pattern.

The above-disclosed subject matter is to be considered illustrative, and not restrictive, and the appended claims are intended to cover all such modifications, enhancements, and other embodiments, which fall within the true spirit and scope of the invention. Thus, to the maximum extent allowed by law, the scope of the invention is to be determined by the broadest permissible interpretation of the following claims and their equivalents, and shall not be restricted or limited by the foregoing detailed description.

What is claimed is:

1. A method of manufacturing an SOI (silicon on insulator) substrate, the method comprising:
preparing a semiconductor substrate;
forming a thermal oxide layer on the semiconductor substrate;
patterning the thermal oxide layer to form a thermal oxide layer pattern exposing a portion of the semiconductor substrate;
forming a first semiconductor single crystal layer covering a sidewall and a top of the thermal oxide layer pattern and contacting the exposed semiconductor substrate; and
forming a second semiconductor single crystal layer on the first semiconductor single crystal layer.

2. The method of claim 1, further comprising removing a portion of the top of the first semiconductor single crystal layer using a planarization process.

3. The method of claim 1, wherein the forming of the first semiconductor single crystal layer comprises:
growing an epitaxial semiconductor layer from the exposed semiconductor substrate using an SEG (selective epitaxial growth) process; and
performing a heat treatment process.

4. The method of claim 1, wherein the forming of the first semiconductor single crystal layer comprises:
forming a semiconductor layer using a deposition method; and
performing a heat treatment process.

5. The method of one of claims 3 and 4, wherein the heat treatment process is performed for duration of between about 10 seconds and about 1 hour, at a temperature between about 110 and about 1200° C., and in an argon or hydrogen atmosphere.

6. The method of claim 4, wherein the semiconductor layer comprises one of amorphous silicon and polysilicon.

7. The method of claim 1, wherein the first semiconductor single crystal layer comprises silicon atoms whose mass number is 28.

8. The method of claim 1, wherein the semiconductor substrate comprises oxygen atoms at an 11 to 14 ppma (parts per million atomic) concentration.

9. The method of claim 1, further comprising forming a metal-gettering site in the semiconductor substrate.

10. The method of claim 9, wherein the forming the metal-gettering site comprises performing a heat treatment process for duration of between about 1 second and about 1 minute, and at a temperature between about 1000 and about 1200° C.

11. The method of claim 9, wherein the forming of the metal-gettering site comprises:
performing a first heat treatment process for duration of between about 2 minutes and about 10 hours, and at a temperature between about 650 and about 800° C.; and
performing a second heat treatment process for duration of between about 2 minutes and about 16 hours, and at a temperature between about 900 and about 1100° C.

12. The method of claim 2, wherein removing the portion of the top of the first semiconductor single crystal layer using the planarization process comprises removing the portion such that the first semiconductor single crystal layer has a thickness of at least about 10 Å on the thermal oxide layer pattern.

13. The method of claim 1, wherein the thermal oxide layer has a thickness of about 5 to about 1500 Å.

14. The method of claim 1, wherein the second semiconductor single crystal layer is formed using an SEG process.

15. An SOI (silicon on insulator) substrate comprising:
a semiconductor substrate;
a thermal oxide layer pattern disposed on the semiconductor substrate;
a first semiconductor single crystal layer contacting a top and a sidewall of the thermal oxide layer pattern and a top of the semiconductor substrate adjacent to the sidewall of the thermal oxide layer pattern; and
a second semiconductor single crystal layer disposed on the first semiconductor single crystal layer.

16. The SOI substrate of claim 15, wherein the first semiconductor single crystal layer comprises silicon atoms whose mass number is 28.

17. The SOI substrate of claim 15, wherein the semiconductor substrate comprises oxygen atoms at an 11 to 14 ppma (parts per million atomic) concentration.

18. The SOI substrate of claim 15, wherein the first semiconductor single crystal layer has a thickness of at least 10 Å on the thermal oxide layer pattern.

19. The SOI substrate of claim 15, wherein the thermal oxide layer has a thickness of about 5 to about 1500 Å.

20. The SOI substrate of claim 15, wherein the semiconductor substrate comprises a metal-gettering site.

21. The SOI substrate of claim 20, wherein the metal-gettering site comprises an oxygen precipitate and wherein the size of the metal-gettering site is about 2 to about 150 nm.

22. A memory device, comprising:
an SOI substrate of claim 15;
a gate pattern disposed on the SOI substrate, and
an impurity implantation region disposed in the SOI substrate and adjacent to the gate pattern.

23. The memory device of claim 22, wherein the gate pattern comprises a gate insulation pattern and a gate electrode pattern which are sequentially stacked.

24. The memory device of claim 22, wherein the gate pattern comprises a tunnel insulation pattern, a charge storage pattern, an interlayer dielectric pattern and a word line which are sequentially stacked.

25. The memory device of claim 24, wherein the charge storage pattern comprises one of a floating gate and a charge trap pattern.

26. The memory of claim 24, wherein the interlayer dielectric pattern comprises one of an interpoly dielectric pattern and a blocking insulation pattern.
